(19) United States
(12) Patent Application Publication
(10) Pub. No.: US 2026/0066219 A1
(43) Pub. Date: Mar. 5, 2026

(54) CHARGED PARTICLE BEAM WRITING METHOD, CHARGED PARTICLE BEAM WRITING APPARATUS, AND NON-TRANSITORY COMPUTER-READABLE STORAGE MEDIUM STORING A PROGRAM

(71) Applicant: NuFlare Technology, Inc., Yokohama-shi (JP)

(72) Inventors: Haruyuki NOMURA, Yokohama-shi (JP); Noriaki NAKAYAMADA, Kamakura-shi (JP)

(73) Assignee: NuFlare Technology, Inc., Yokohama-shi (JP)

(21) Appl. No.: 19/294,412

(22) Filed: Aug. 8, 2025

(30) Foreign Application Priority Data
Aug. 29, 2024 (JP) 2024-147071

(51) Int. Cl. H01J 37/304; G03F 1/22; H01J 37/317

(52) U.S. Cl. CPC H01J 37/304; G03F 1/22; H01J 37/3174; H01J 2237/31798

(57) ABSTRACT

According to one aspect of the present invention, a charged particle beam writing method includes calculating a positional deviation amount distribution which defines an amount of positional deviation, at a time of irradiation by a charged particle beam to a target object, deviated from a design position due to an irreversible deformation at each position of the target object which deforms irreversibly depending on a dose distribution of the charged particle beam and includes a substrate body, a multilayer film arranged on the substrate body and reflecting a light, and an absorber film arranged on the multilayer film and absorbing the light, and calculating, using the positional deviation amount distribution, a correction amount for correcting an irradiation position of the charged particle beam such that a defect occurred in the target object is included in a region where the absorber film remains after writing.

### CROSS-REFERENCE TO RELATED APPLICATION

This application is based upon and claims the benefit of priority from prior Japanese Patent Application No. 2024-147071 filed on Aug. 29, 2024 in Japan, the entire contents of which are incorporated herein by reference.

### BACKGROUND OF THE INVENTION

### Field of the Invention

One aspect of embodiments of the present invention relates to a charged particle beam writing method, a charged particle beam writing apparatus, and a non-transitory computer-readable storage medium storing a program. For example, it relates to a method for writing patterns on a substrate which irreversibly deforms due to irradiation by electron beams.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is becoming increasingly finer year by year. The electron beam writing technique, which intrinsically has excellent resolution, is used for writing or “drawing” on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple beam system forms multiple beams by letting an electron beam emitted from an electron gun pass through a mask having a plurality of holes, performs blanking control for each beam, reduces each unblocked beam by an optical system, and deflects, by a deflector, a reduced beam to be applied to a desired position on a target object or “sample”.

Here, a reflective optical system is proposed for an exposure method using an EUV light. Therefore, a reflection-type mask where a multilayer film is formed on the substrate is employed. The multilayer film formed by alternately layering molybdenum (Mo) and silicon (Si) is used.

If the regularity of each layer thickness of these laminated layers breaks down, the phase of a reflected light deviates. As a result, a phase defect will be exposed on the wafer. Therefore, desirably, there is no defect on the surface of the multilayer substrate. Furthermore, desirably, foreign material which may generate a defect is prevented from being included in the multilayer film. However, it is difficult to completely reduce the defect rate of the substrate to zero, and if selecting only a substrate that has no defect or satisfies specification after inspecting all fabricated masks, it makes the substrate very expensive. Then, in order to avoid transferring and printing a defect of a mask in exposure processing, there is disclosed a technique in which a phase defect on a multilayer mask is prevented from being transferred or printed by forming the mask after offsetting the position of a pattern so that a defect is included in the region of an absorber pattern (e.g., refer to Japanese Patent Application Laid-open (JP-A) No. 2015-043100).

Regarding a mask substrate, the position precision of a pattern to be written on the mask substrate is important. One of factors which degrade the precision of global pattern position is that, in a glass substrate serving as a target object, a reversible deformation occurs such as a thermal expansion caused by glass substrate heating due to electron beam irradiation and its subsequent contraction. The glass substrate deformation results in a problem that positional deviation occurs at a beam irradiation position or a pattern formation position.

Meanwhile, as a technique for solving the above problem, a blanks maker manufacturing glass substrates has developed a low-thermal expansion material (LTEM) substrate in which thermal expansion of the substrate itself is suppressed. In the LTEM substrate, since thermal expansion caused by temperature increase due to irradiation by electron beams is small, substrate deformation resulting from the thermal expansion can be suppressed, which has solved problems such as positional deviation by a reversible deformation accompanied by the thermal expansion. However, it has turned out that an irreversible contraction phenomenon occurs in a glass substrate due to irradiation by electron beams. This has a background where the sensitivity of resist is lowered in order to improve the local dimensional accuracy, which results in the beam dose having been increased, and where since the thermal expansion has become negligible because of prevalence of the LTEM substrate, relatively, the contraction phenomenon of the glass substrate has become revealed. Then, a problem arises because irreversible deformation of the glass substrate occurring due to a contraction phenomenon degrades the global position precision of a beam irradiation position or a pattern formation position.

Thus, even if, in an EUV mask, the position of a pattern is offset by the conventional method so that a defect may be included in the region of an absorber pattern, a problem occurs that, because of irreversible deformation of the substrate by a contraction phenomenon, the defect deviates out of the region of the absorber pattern, resulting in being inside the region of the multilayer film. This problem occurs both in multiple beam writing and in single beam writing.

### BRIEF SUMMARY OF THE INVENTION

According to one aspect of the present invention, a charged particle beam writing method includes calculating a positional deviation amount distribution which defines an amount of positional deviation, at a time of irradiation by a charged particle beam to a target object, deviated from a design position due to an irreversible deformation at each position of the target object which deforms irreversibly depending on a dose distribution of the charged particle beam and includes a substrate body, a multilayer film arranged on the substrate body and reflecting a light, and an absorber film arranged on the multilayer film and absorbing the light,
calculating, using the positional deviation amount distribution, a correction amount for correcting an irradiation position of the charged particle beam such that a defect occurred in the target object is included in a region where the absorber film remains after writing, and
correcting the irradiation position by using the correction amount, and writing a pattern on the target object with the charged particle beam.

According to another aspect of the present invention, a charged particle beam writing apparatus includes
a positional-deviation amount distribution calculation circuit configured to calculate a positional deviation amount distribution defining an amount of positional deviation, at a time of irradiation by a charged particle beam to a target object, deviated from a design position due to an irreversible deformation at each position of the target object which deforms irreversibly depending on a dose distribution of the charged particle beam and includes a substrate body, a multilayer film arranged on the substrate body and reflecting an EUV light, and an absorber film arranged on the multilayer film and absorbing the EUV light,
a correction amount calculation circuit configured to calculate, using the positional deviation amount distribution, a correction amount for correcting an irradiation position of the charged particle beam such that a defect occurred in the target object is included in a region where the absorber film remains after writing, and
a writing mechanism configured to write a pattern on the target object with the charged particle beam whose irradiation position has been corrected using the correction amount.

According to yet another aspect of the present invention, a non-transitory computer-readable storage medium storing a program for causing a computer to execute processing includes
calculating a positional deviation amount distribution which defines an amount of positional deviation, at a time of irradiation by a charged particle beam to a target object, deviated from a design position due to an irreversible deformation at each position of the target object which deforms irreversibly depending on a dose distribution of the charged particle beam and includes a substrate body, a multilayer film arranged on the substrate body and reflecting an EUV light, and an absorber film arranged on the multilayer film and absorbing the EUV light,
storing the positional deviation amount distribution having been calculated, in a storage device, and
reading the positional deviation amount distribution from the storage device, calculating, by using the positional deviation amount distribution, a correction amount for correcting an irradiation position of the charged particle beam such that a defect occurred in the target object is included in a region where the absorber film remains after writing, and outputting the correction amount.

### BRIEF DESCRIPTION OF THE DRAWINGS

FIG. 1 is a schematic diagram showing a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is an illustration showing an example of an evaluation substrate according to the first embodiment;

FIG. 5 is an illustration showing an example concerning a positional deviation amount of an evaluation substrate, and an example of deformation of a substrate according to the first embodiment;

FIG. 6 is an illustration showing an example of a state at the time of beam irradiation to an evaluation substrate according to the first embodiment;

FIG. 7 is an illustration showing an example of a stress state resulting from beam irradiation to an evaluation substrate according to the first embodiment;

FIG. 8 is an illustration showing an example of a sectional view of an EUV mask where a defect exists in a reflection region according to a comparative example 1 of the first embodiment;

FIG. 9 is an illustration showing an example of a sectional view of an EUV mask where a defect exists in an absorber region according to the first embodiment;

FIG. 10 is a top view showing an example of a positional relationship between a defect and an absorber film before writing a defect portion according to a comparative example 2 of the first embodiment;

FIG. 11 is a top view showing an example of a positional relationship between a defect and an absorber film at the time of writing a defect portion according to the comparative example 2 of the first embodiment;

FIG. 12 is a flowchart showing an example of main steps of a writing method according to the first embodiment;

FIG. 13 is an illustration showing a configuration of a target object according to the first embodiment;

FIG. 14 is an illustration showing an example of a positional relationship between a pattern layout and a defect according to the first embodiment;

FIG. 15 is a conceptual diagram for explaining an example of each region on a target object and an example of a writing operation according to the first embodiment;

FIG. 16 is an illustration showing an example of an irradiation region of multiple beams and a writing target pixel according to the first embodiment;

FIG. 17 is a graph showing an example of a relationship between a substrate contraction ratio and a dose according to the first embodiment;

FIG. 18 is an illustration showing an example of a model by a finite element method according to the first embodiment;

FIG. 19 is an illustration for explaining an example of a multiple beam writing operation according to the first embodiment;

FIG. 20 is a top view showing an example of a positional relationship between a defect and an absorber film at the time of writing a defect portion according to the first embodiment; and

FIG. 21 is a top view showing an example of a positional relationship between a defect and an absorber film after completing writing according to the first embodiment.

### DETAILED DESCRIPTION OF THE INVENTION

Embodiments below provide a method and apparatus capable of correcting that a defect deviates out of the region of an absorber pattern due to irreversible deformation of an EUV mask substrate caused by irradiation with a charged particle beam.

Embodiments below describe a configuration in which an electron beam is used as an example of a charged particle beam. The charged particle beam is not limited to the electron beam, and other charged particle beams such as an ion beam may also be used. Furthermore, Embodiments describe the case of using multiple beams composed of a plurality of electron beams. However, the correction method described below is not limited to the case of multiple beams, and a single beam case is also applicable.

### First Embodiment

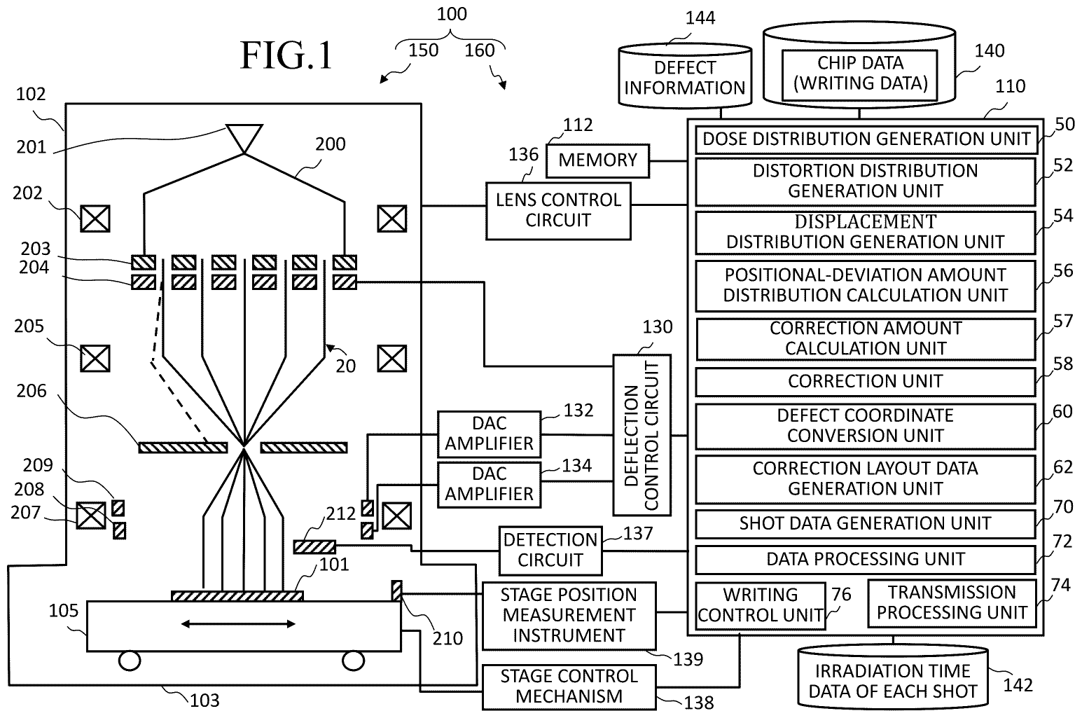

FIG. 1 is a schematic diagram showing a configuration of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus and a multiple charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, a deflector 208, a deflector 209, and a detector 212.

In the writing chamber 103, an XY stage 105 is disposed. On the XY stage 105, there is placed a target object or “sample” 101 such as a mask serving as a writing target substrate when writing (exposure) is performed. The backside of the target object 101 is supported at three points by three rod-shaped support members (not shown), for example. The target object 101 may be, for example, a mask for EUV exposure (EUV mask) used in fabricating semiconductor devices and the like. Furthermore, the target object 101 may be a mask blank on which resist has been applied and nothing has yet been written. A low-thermal expansion material (LTEM) substrate is used as a glass substrate of the target object 101. The target object 101 includes a substrate body being an LTEM substrate, a multilayer film which is arranged on the substrate body and reflects an EUV light, and an absorber film which is arranged on the multilayer film and absorbs an EUV light. In addition, resist is applied to the surface.

Furthermore, on the XY stage 105, a mirror 210 for measuring the position of the XY stage 105 is placed.

The control system circuit 160 includes a control computer 110, a memory 112, a deflection control circuit 130, a correcting lens control circuit 131, digital-analog converter (DAC) amplifier units 132 and 134, a lens control circuit 136, a detection circuit 137, a stage control mechanism 138, a stage position measurement instrument 139, and storage devices 140, 142, and 144 such as magnetic disk drives. The control computer 110, the memory 112, the deflection control circuit 130, the lens control circuit 136, the detection circuit 137, the stage control mechanism 138, the stage position measurement instrument 139, and the storage devices 140, 142, and 144 are connected to each other through a bus (not shown). The DAC amplifier units 132 and 134 and the blanking aperture array mechanism 204 are connected to the deflection control circuit 130. The deflector 209 is composed of at least four electrodes (or “four poles”), and controlled by the deflection control circuit 130 through the DAC amplifier unit 132 disposed for each electrode. The deflector 208 is composed of at least four electrodes (or “four poles”), and controlled by the deflection control circuit 130 through the DAC amplifier unit 134 disposed for each electrode. Electromagnetic lenses such as the illumination lens 202, the reducing lens 205, and the objective lens 207 are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

The detector 212 detects a secondary electron emitted from the surface of the target object due to that the target object surface is irradiated by an electron beam for measuring the mark. The detected signal is output to the detection circuit 137, and after being amplified and converted into digital data, it is output to the control computer 110.

In the control computer 110, there are arranged a dose distribution generation unit 50, a distortion distribution generation unit 52, a displacement distribution generation unit 54, a positional-deviation amount distribution calculation unit 56, a correction amount calculation unit 57, a correction unit 58, a defect coordinate conversion unit 60, a correction layout data generation unit 62, a shot data generation unit 70, a data processing unit 72, a transmission processing unit 74, and a writing control unit 76. Each of the “ . . . units” such as the dose distribution generation unit 50, the distortion distribution generation unit 52, the displacement distribution generation unit 54, the positional-deviation amount distribution calculation unit 56, the correction amount calculation unit 57, the correction unit 58, the defect coordinate conversion unit 60, the correction layout data generation unit 62, the shot data generation unit 70, the data processing unit 72, the transmission processing unit 74, and the writing control unit 76 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the dose distribution generation unit 50, the distortion distribution generation unit 52, the displacement distribution generation unit 54, the positional-deviation amount distribution calculation unit 56, the correction amount calculation unit 57, the correction unit 58, the defect coordinate conversion unit 60, the correction layout data generation unit 62, the shot data generation unit 70, the data processing unit 72, the transmission processing unit 74, and the writing control unit 76, and information being operated are stored in the memory 112 each time.

Writing operations of the writing apparatus 100 are controlled by the writing control unit 76. Processing of transmitting irradiation time data of each shot to the deflection control circuit 130 is controlled by the transmission control unit 74.

Writing data (chip data) is input from the outside of the writing apparatus 100, and stored in the storage device 140. Chip data defines information on a plurality of figure patterns configuring a chip pattern. Specifically, for example, a coordinate sequence of each vertex coordinate is defined for each figure pattern. A figure code and the like may also preferably be defined. Furthermore, a figure code, coordinates, and a size may also preferably be defined.

Defect information on a defect of the target object 101 is input from the outside of the writing apparatus 100, and stored in the storage device 144, for example. The defect information defines the position (coordinates), the size, and the like of a defect of the target object 101 measured by a defect measuring device.

FIG. 1 shows a configuration necessary for describing the first embodiment. Other configuration elements generally necessary for the writing apparatus 100 may also be included therein.

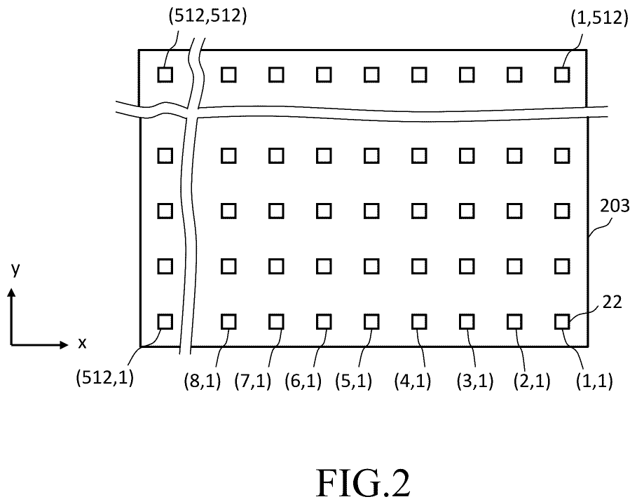

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes (openings) 22 of 512×512, that is 512 holes in the y direction and 512 holes in the x direction, are formed. The number of holes 22 is not limited thereto. For example, it is also preferable to form the holes 22 of 32×32. Each of the holes 22 is a rectangle (including a square) having the same dimension and shape as each other. Alternatively, each of the holes 22 may be a circle with the same diameter as each other. The multiple beams 20 are formed by letting portions of an electron beam 200 individually pass through a corresponding one of a plurality of holes 22. In other words, the shaping aperture array substrate 203 forms and emits the multiple beams 20. The shaping aperture array substrate 203 is an example of an emission source of the multiple beams 20.

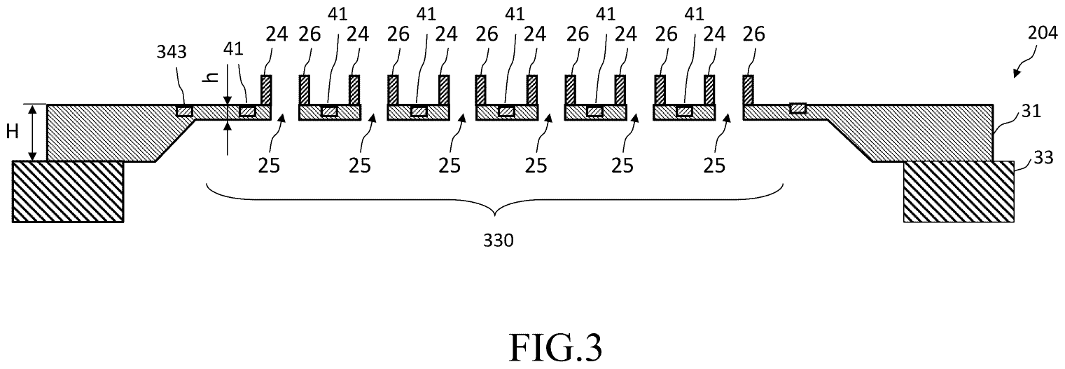

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support substrate 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. In regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam ON condition by passing through the limiting aperture substrate 206. Blanking control is provided by such deflection.

Next, operations of the writing mechanism 150 will be described. The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated by the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. The electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in an OFF state by the blanker of the blanking aperture array mechanism 204. Then, one shot of each beam is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the deflectors 208 and 209 in order to irradiate respective beam irradiation positions on the target object 101. For example, when the XY stage 105 is continuously moving, tracking control is performed by the deflector 208 so that the beam irradiation position may follow the movement of the XY stage 105. Ideally, the multiple beams 20 irradiating at a time are aligned at the pitch obtained by multiplying the arrangement pitch of a plurality of holes 22 in the shaping aperture array substrate 203 by the desired reduction ratio described above.

By using an LTEM substrate as a substrate body part, which serves as a writing target object, thermal expansion due to irradiation by electron beams such as a single beam or multiple beams may hardly occur. Therefore, the problem of positional deviation of the writing position because of thermal expansion has been improved greatly to be a negligible extent. However, it has turned out that an irreversible contraction phenomenon arises in the glass substrate used as the substrate body of the target object 101 because dose amounts are accumulated through a plurality of times of irradiation with electron beams.

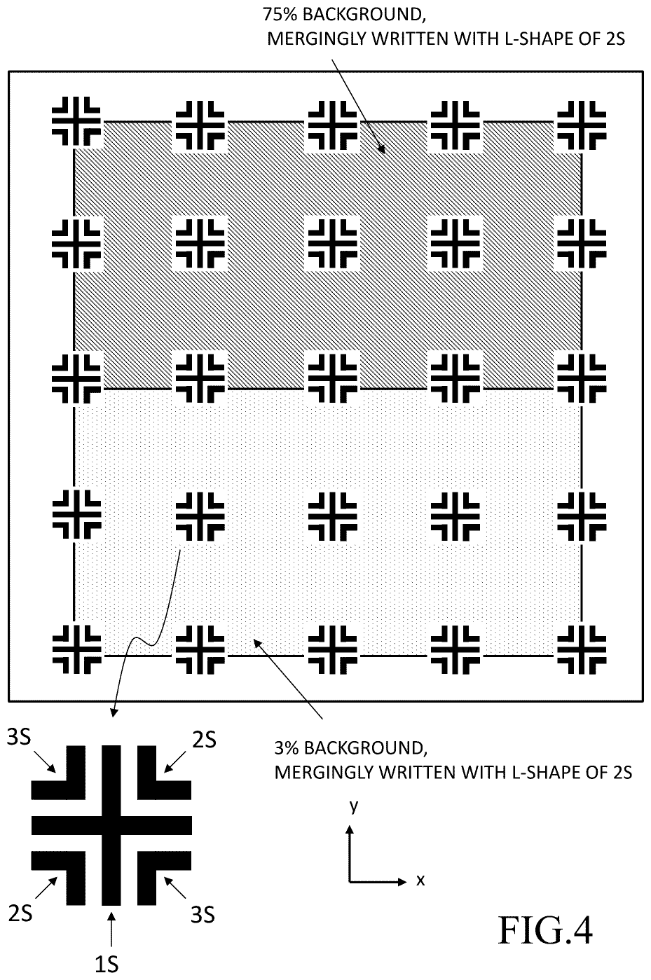

FIG. 4 is an illustration showing an example of an evaluation substrate according to the first embodiment. An LTEM substrate is used as an evaluation substrate. Specifically, a mask blank is used, in which a chromium (Cr) film, for example, is formed on the LTEM substrate and a resist film is formed on the Cr film. FIG. 4 shows an example of a pattern in the state where a writing process has been performed three times. Each writing process is performed in the y direction from the lower side to the upper side of the evaluation substrate. In the first writing process (1S), a plurality of cross patterns are written in a grid form on the whole evaluation substrate. In the second writing process (2S), L patterns are written close to each cross pattern, for example, at the upper right and the lower left of each cross pattern, and rectangular patterns whose pattern densities are different from each other at the lower half and the upper half of the evaluation substrate are written as a background of a plurality of cross patterns. For example, the pattern density of the background at the lower half part which is written in the first half is set to 3%. The pattern density of the background at the upper half part which is written in the latter half is set to 75%. In the third writing process (3S), L patterns are written close to each cross pattern, for example, at the upper left and the lower right of each cross pattern. After each writing process, the position of each written pattern is measured by a position measurement instrument (not shown).

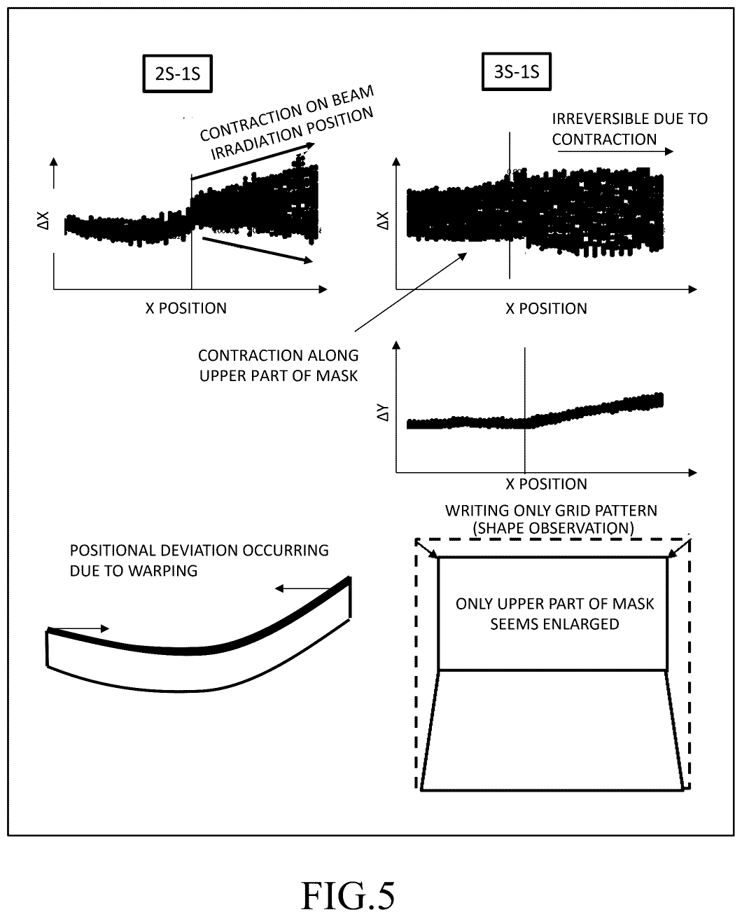

FIG. 5 is an illustration showing an example concerning a positional deviation amount of an evaluation substrate, and an example of deformation of a substrate according to the first embodiment. The upper left graph (2S-1S) of FIG. 5 shows an example of an x-direction positional deviation amount Δx in the state, (2S-1S), where the position of each pattern after the writing process 1S is subtracted from the position of each pattern after the writing process 2S. As shown in the graph of (2S-1S), it turns out that the positional deviation amount Δx is small in the pattern whose background has a pattern density of 3%, whereas, in the pattern whose background has a pattern density of 75%, the positional deviation amount Δx increases associated with an increase of the region where the writing process has been performed. This means that deformation by contraction of the glass substrate increases depending on the dose amount. Furthermore, the upper right graphs (3S-1S) of FIG. 5 show an example of an x-direction positional deviation amount Δx and a y-directional positional deviation amount Δy in the state, (3S-1S), where the position of each pattern after the writing process 1S is subtracted from the position of each pattern after the writing process 3S. As shown in the graph of (3S-1S), the positional deviation amount Δx of 2S still remains after 3S. It turns out that the lower half of the substrate also deforms corresponding to the contraction of the upper half of the substrate, and since deviation occurs at the position of the substrate at 3S, the positional deviation amount Δx increases. Furthermore, it turns out that, with respect also to the y direction in the upper half of the substrate, the positional deviation amount ΔY increases gradually. This is because that, as shown in the lower right side of FIG. 5, the upper half of the substrate is irradiated with a comparative large amount of beam, and therefore, deformation occurs because of a large contraction in the upper half. As shown in the figure, by 2S, deformation because of a large contraction occurs in the upper half of the substrate.

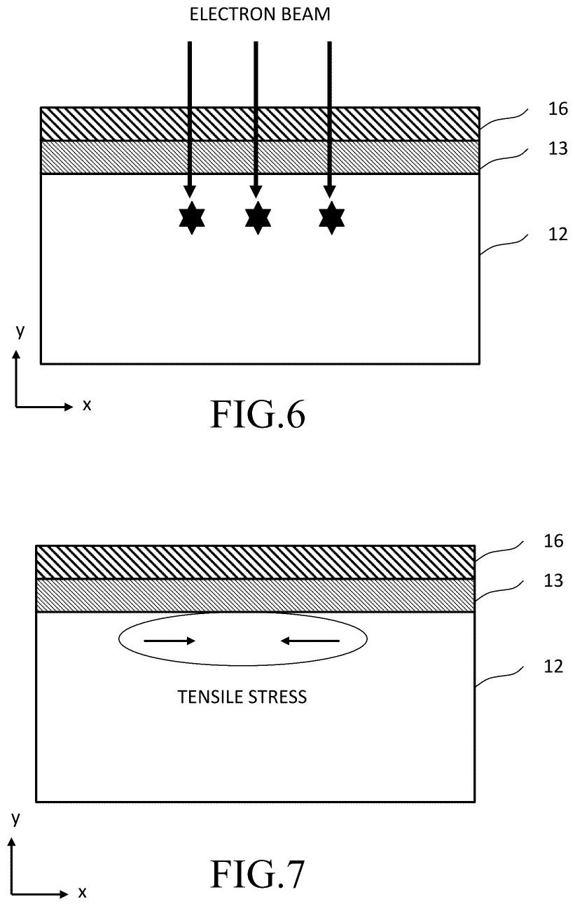

FIG. 6 is an illustration showing an example of a state at the time of beam irradiation to an evaluation substrate according to the first embodiment.

FIG. 7 is an illustration showing an example of a stress state resulting from beam irradiation to an evaluation substrate according to the first embodiment.

As described above, as the evaluation substrate of FIG. 6, a mask blank is used, in which, for example, a chromium (Cr) film 13 is formed on an LTEM substrate 12 and a resist film 16 is formed on the Cr film 13. When the evaluation substrate is irradiated by an electron beam, the electron beam reaches the LTEM substrate 12 and penetrates it up to a depth of about several tens of μm from the surface of the LTEM substrate 12. By this, an irreversible local contraction occurs on the irradiation position of the LTEM substrate 12. In the case where a plurality of portions are irradiated by beams, a tensile stress occurs in the vicinity of the substrate surface due to a local contraction, in the whole region having been irradiated with beams. By this, in the vicinity of the surface of the LTEM substrate 12, an irreversible deformation occurs due to a contraction phenomenon. Since a deformation having a depth of, for example, 20 μm is small volume-wise compared to the width dimension (e.g., 6.35 mm) of the LTEM substrate 12, the property of thermal deformation of the whole substrate does not change. Therefore, a reversible deformation resulting from a thermal expansion can be negligible.

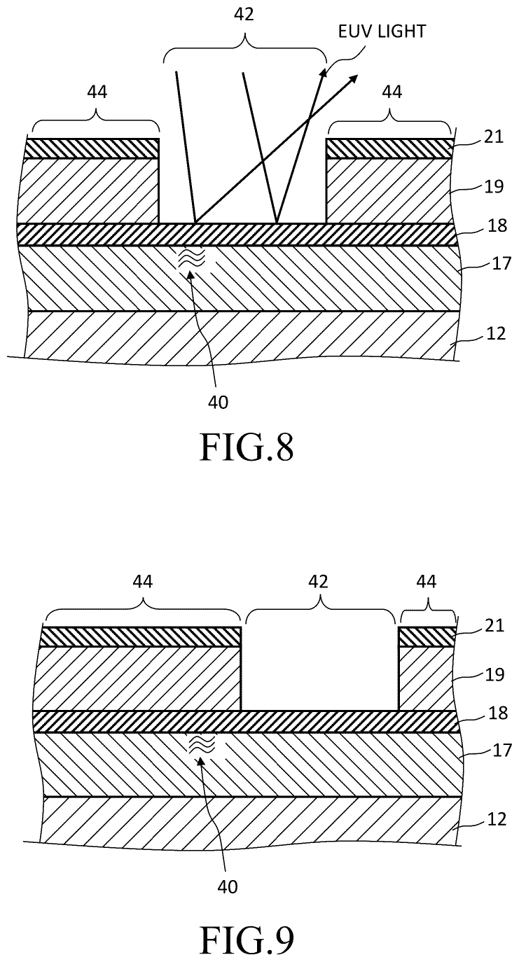

FIG. 8 is an illustration showing an example of a sectional view of an EUV mask where a defect exists in a reflection region according to a comparative example 1 of the first embodiment.

FIG. 9 is an illustration showing an example of a sectional view of an EUV mask where a defect exists in an absorber region according to the first embodiment.

The EUV mask is formed such that a multilayer film 17 composed of, for example, several tens of alternately laminated layers of molybdenum (Mo) and silicon (Si) is applied all over the surface of the LTEM substrate 12. A cap film 18, such as ruthenium (Ru), is applied on the whole surface of the multilayer film 17. The cap film 18 is exposed at the region where EUV lights are reflected. In contrast, at the region where EUV lights are not reflected, an absorber film 19 which absorbs EUV lights and an antireflection film 21 are formed in order on the cap film 18. As shown in FIG. 8, if a defect 40 of the multilayer film 17 exists in a region 42 where the absorber film 19 does not exist, the phase of a reflected EUV light deviates. As a result, when a pattern is transferred or printed onto a semiconductor wafer by using this EUV mask, the position of the pattern deviates. Thus, according to the first embodiment, as shown in FIG. 9, after the patterning, writing is performed using data in which the pattern layout has been shifted from the position shown in FIG. 8 so that the position of the defect 40 may be included in a region 44, where the absorber film 19 exists. To explain specifically, patterning of the target object 101 is performed as follows: a pattern is written by the writing apparatus 100 on the target object 101 being an EUV mask blank coated with a resist film, the resist is developed, the antireflection film 21 and the absorber film 19 are etched by using the resist pattern, as a mask, which is formed of the resist film remaining after the development, and the remaining resist film is removed by ashing. Through such patterning, the EUV mask is fabricated. Then, after the patterning, when writing is performed by the writing apparatus 100, the pattern layout is shifted such that the position of the defect 40 is included in the region 44 where the absorber film 19 exists. In order to shift the pattern layout, first, it is necessary to specify the position of a defect. Therefore, a phase defect inspection of the target object 101 should be performed by a defect inspection apparatus (not shown) before writing in order to specify the position of the defect 40.

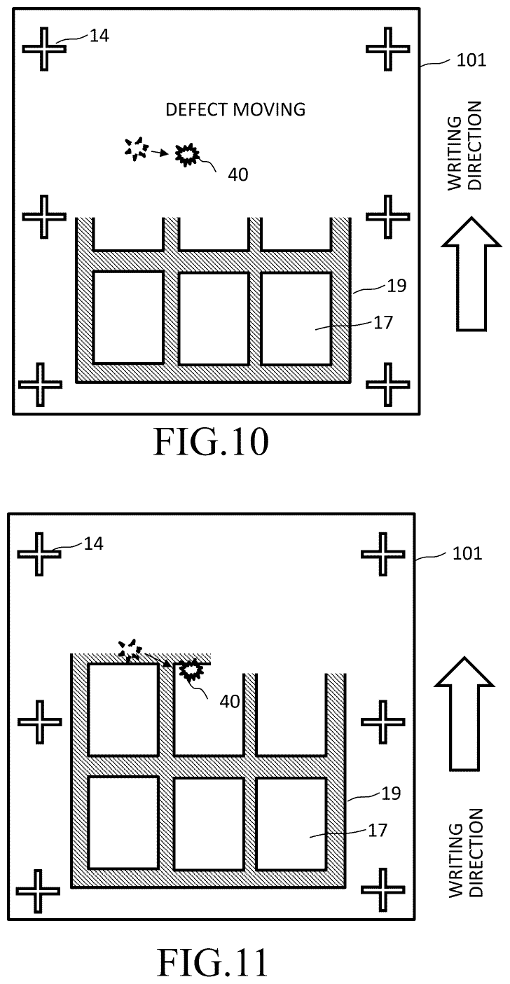

FIG. 10 is a top view showing an example of a positional relationship between a defect and an absorber film before writing a defect portion according to a comparative example 2 of the first embodiment.

FIG. 11 is a top view showing an example of a positional relationship between a defect and an absorber film at the time of writing a defect portion according to the comparative example 2 of the first embodiment.

In the comparative example 2, as shown in FIG. 9, at the stage before starting writing, the pattern layout is offset in advance so that the defect 40 may be included, after writing, in a pattern in the absorber film 19, and then, the writing is started. In that case, while about a half of the writing region is written, as shown in FIG. 10, the position of the defect 40 is physically moved associated with an irreversible deformation of the substrate described above. Then, when the portion where the defect 40 exists is irradiated by an electron beam, as shown in FIG. 11, the position of the defect 40 is further physically moved. Therefore, at the time of the portion where the defect 40 exists in defect information being irradiated by an electron beam, there is a case in which the position of the defect 40 deviates out of a pattern which is for the absorber film 19 to remain. This means that, as shown in FIG. 8, the defect 40 exists in the reflection region of the multilayer film 17 on which the absorber film 19 does not exist. Consequently, if a pattern is transferred or printed on the semiconductor wafer by using this fabricated EUV mask, the phase of a reflected EUV light deviates, and therefore, the position of the pattern deviates.

Then, according to the first embodiment, before starting writing, a positional deviation amount distribution of the substrate body (LTEM substrate 12) of the target object 101 at the time of applying an electron beam to the portion where the defect 40 exists is acquired in advance. With respect to the data in which the layout has been offset so that the defect whose position is defined in the defect information can be included in the region of the absorber film, a correction is performed by further adding, as an offset amount, an amount of positional deviation of the substrate caused by irreversible deformation of the substrate. Specifically, it is described below.

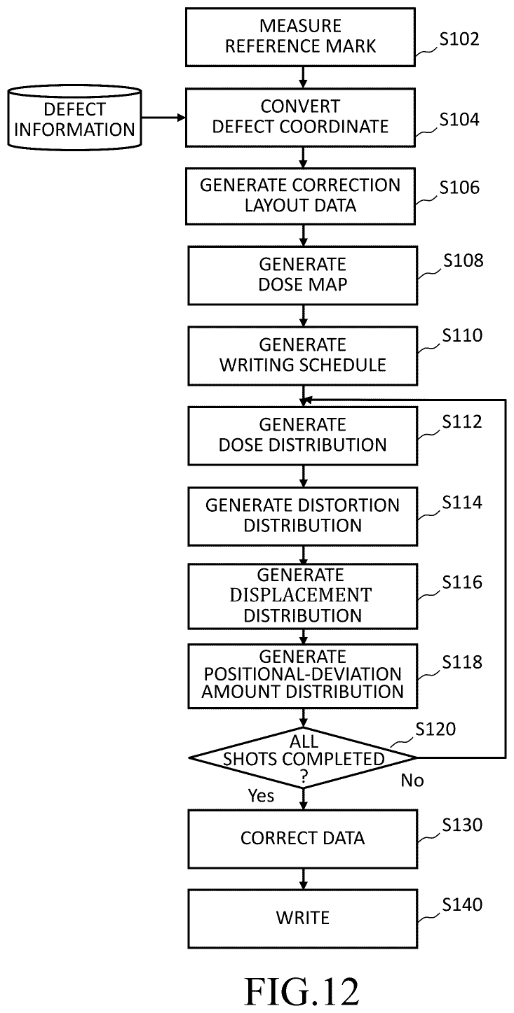

FIG. 12 is a flowchart showing an example of main steps of a writing method according to the first embodiment. In FIG. 12, the writing method of the first embodiment executes a series of steps: a reference mark measurement step (S102), a defect coordinate conversion step (S104), a correction layout data generation step (S106), a dose map generation step (S108), a writing schedule generation step (S110), a dose distribution generation step (S112), a distortion distribution generation step (S114), a displacement distribution generation step (S116), a positional-deviation amount distribution generation step (S118), a determination step (S120), a data correction step (S130), and a writing step (S140).

In the reference mark measurement step (S102), under the control of the writing control unit 76, the writing mechanism 150 measures the position of a reference mark by scanning over the reference mark formed on the target object 101.

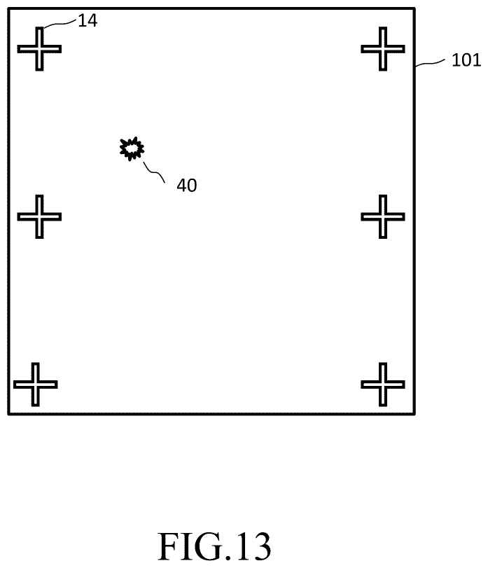

FIG. 13 is an illustration showing a configuration of a target object according to the first embodiment. In FIG. 13, a plurality of reference marks 14 are arranged in the region surrounding the writing region of the target object 101. It is preferable to use, for example, a cross pattern as each of the reference marks 14. First, the XY stage 105 is moved so that one of the plurality of reference marks 14 may be in the irradiation range of an electron beam. Then, for example, the reference mark 14 is scanned with a representation beam (e.g., the center beam) of the multiple beams 20. Specifically, beams other than the representation beam are set to be beam OFF by the blanking aperture array mechanism 204. By deflecting the representation beam by the main deflector 208, the representation beam scans the region including the reference mark 14. Secondary electrons emitted from the target object 101 through the scanning are detected by the detector 212, and converted into digital data in the detection circuit 137 to be output to the control computer 110. The other reference marks 14 are similarly scanned. The writing control unit 76 measures the position of each reference mark obtained by the scanning. When writing, the position on the surface of the target object is defined using at least two of the plurality of reference marks 14. Therefore, the pattern layout to be written is adjusted based on the coordinate system which originates from the reference mark 14. Thereby, even when the arrangement position on the stage of the target object 101 is displaced, it is possible to write a pattern on a desired position of the target object 101.

In the defect coordinate conversion step (S104), the defect coordinate conversion unit 60 reads defect information from the storage device 144, and converts the position of the defect defined in the defect information into the position (coordinates) with respect to the reference mark 14. There is a case where the coordinate system in which the coordinates of the defect are defined by a defect measurement device and the coordinate system generated based on the reference mark 14 are different from each other. Therefore, the defect coordinate conversion unit 60 converts the position of the defect defined in the defect information into the position (coordinates) with respect to the reference mark 14.

In the correction layout data generation step (S106), the correction layout data generation unit 62 generates correction layout data in which the position of the pattern layout is offset.

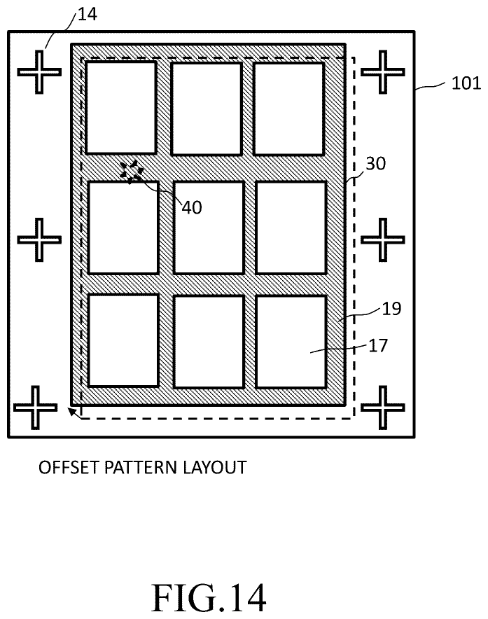

FIG. 14 is an illustration showing an example of a positional relationship between a pattern layout and a defect according to the first embodiment. As described above, it is unknown whether the pattern layout to be written from now on can include the defect 40 in the pattern region of the absorber film 19. Then, the correction layout data generation unit 62 performs correction by offsetting the position of the pattern layout so that the defect 40 acquired based on the reference mark 14 may be included in the pattern region of the absorber film 19. FIG. 14 shows the case where the writing region 30 (chip region) is offset up to the position where the defect 40 can be included in the pattern region of the absorber film 19. Data of the pattern layout having been offset is stored in the storage device 140, for example. If a plurality of defects exist in the target object, the position of the pattern layout is offset so that as many defects as possible can be included in the pattern region of the absorber film 19. If the number of defects which cannot be included in the pattern region of the absorber film 19 even after the correction is more than an allowable number, it is treated as an error to be ended.

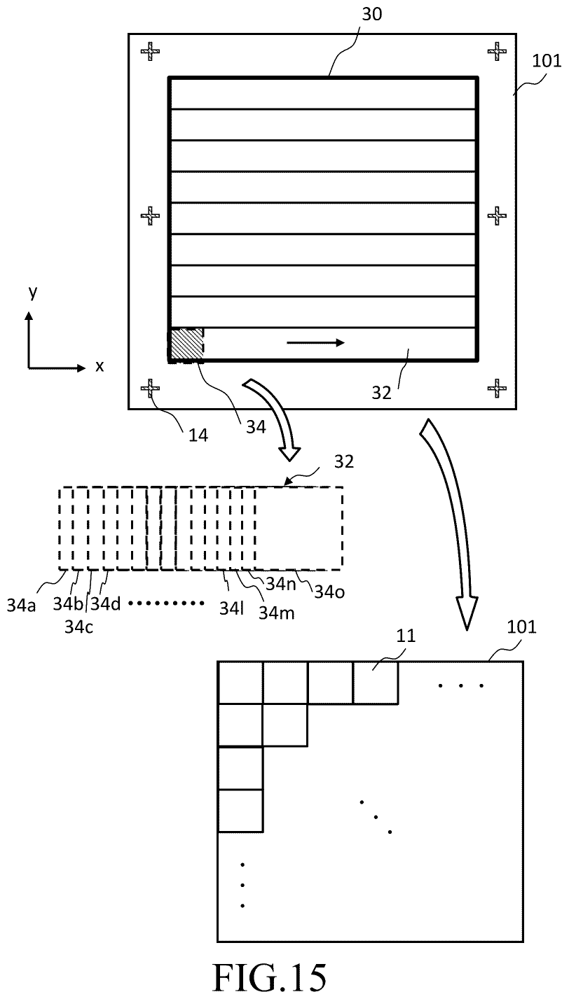

FIG. 15 is a conceptual diagram for explaining an example of each region on a target object and an example of a writing operation according to the first embodiment. As shown in FIG. 15, a writing region 30 (bold line) of the target object 101 is defined based on the position of a reference mark 14. The writing region 30 (bold line) is virtually divided into a plurality of stripe regions 32 by a predetermined width in the y direction, for example. In the case of FIG. 15, the writing region 30 of the target object 101 is divided into a plurality of stripe regions 32 by the width size being substantially the same as the design size of an irradiation region 34 (beam array region) which can be irradiated with one irradiation by the multiple beams 20. The x-direction design size of the irradiation region 34 of the multiple beams 20 can be defined by (the number of x-direction beams)×(x-direction beam pitch). The y-direction size of the rectangular irradiation region 34 can be defined by (the number of y-direction beams)×(y-direction beam pitch).

First, the XY stage 105 is moved to make an adjustment such that the irradiation region 34 of the multiple beams 20 is located at the left end, or at a position further left than the left end, of the first stripe region 32, and then writing of the first stripe region 32 is performed. When writing the first stripe region 32, the XY stage 105 is moved, for example, in the −x direction, so that the writing may proceed relatively in the x direction. The XY stage 105 is moved, for example, continuously at a constant speed. After writing the first stripe region 32, the stage position is moved in the −y direction by the width of the stripe region 32.

Next, an adjustment is made such that the irradiation region 34 of the multiple beams 20 is located at the left end, or at a position further left than the left end, of the second stripe region 32. Then, writing of the second stripe region 32 is performed by moving the XY stage 105 in the −x direction, for example, to proceed the writing relatively in the x direction. Henceforth, similarly, writing is performed towards the upper side (in the y direction) in order from the stripe region 32 at the lower side.

FIG. 15 shows the case where respective stripe regions 32 are written in the same direction, but, it is not limited thereto. For example, with respect to the stripe region 32 to be written following the stripe region 32 having been written in the x direction, it may be written in the −x direction by moving the XY stage 105 in the x direction, for example. Thus, due to performing writing while alternately changing the writing direction, the stage moving time can be reduced, which results in reducing the writing time. Owing to one shot of multiple beams 20 having been formed by individually passing through the holes 22 in the shaping aperture array substrate 203, a plurality of shot patterns up to the number of the holes 22 are maximally formed at a time.

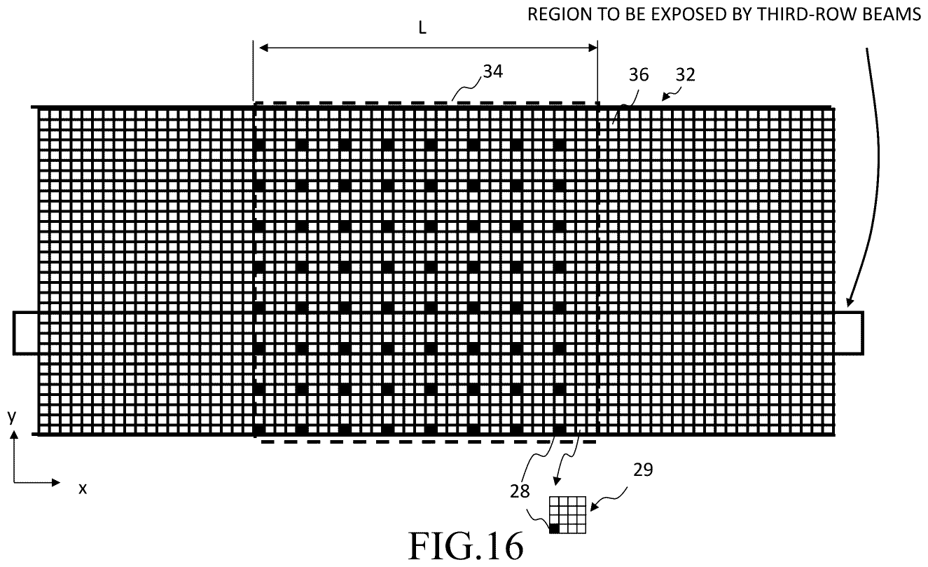

FIG. 16 is an illustration showing an example of an irradiation region of multiple beams and a pixel to be written (writing target pixel) according to the first embodiment. In FIG. 16, the stripe region 32 is divided into a plurality of mesh regions by the beam size of the multiple beams 20, for example. Each mesh region serves as a writing target pixel 36 (unit irradiation region, irradiation position, or writing position). The size of the writing pixel 36 is not limited to the beam size, and may be any size regardless of beam size. For example, it may be 1/n (n being an integer of 1 or more) of the beam size. FIG. 16 shows the case where the writing region of the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the rectangular, including square, irradiation region 34 can be defined by (the number of x-direction beams)×(beam pitch in the x direction). The y-direction size of the rectangular irradiation region 34 can be defined by (the number of y-direction beams)×(beam pitch in the y direction). FIG. 16 shows the case of multiple beams of 512×512 (rows×columns) having been simplified to 8×8 (rows×columns). In the irradiation region 34, there are shown a plurality of pixels 28 (beam writing positions) which can be irradiated with one shot of the multiple beams 20. The pitch between adjacent pixels 28 is the beam pitch of the multiple beams. A sub-irradiation region 29 (pitch cell) is configured by a rectangular, including square, region surrounded by the size of beam pitches in the x and y directions. In the example of FIG. 16, each sub-irradiation region 29 is composed of 4×4 pixels, for example.

In the dose map generation step (S108), the shot data generation unit 70 generates a dose map, to be described later, in which a dose amount is defined for each pixel. Specifically, it operates as follows: The shot data generation unit 70 calculates, for each pixel 36, a pattern area density p′ of a pattern arranged in the proximity mesh region concerned, as a rasterization processing.

Next, the shot data generation unit 70 virtually divides a writing region (e.g., stripe region) into a plurality of proximity mesh regions (mesh regions for proximity effect correction calculation) by a predetermined size. The size of the proximity mesh region is preferably set to be about 1/10 of the influence range of the proximity effect, such as about 1 μm. Then, the shot data generation unit 70 reads writing data from the storage device 140, and calculates, for each proximity mesh region, a pattern area density ρ″ of a pattern arranged in the proximity mesh region concerned.

Next, the shot data generation unit 70 calculates, for each proximity mesh region, a proximity effect correction dose Dp(x) for correcting a proximity effect. An unknown proximity effect correction dose Dp(x) can be defined by a threshold value model for proximity effect correction, which is the same as the one used in a conventional method, where a backscatter coefficient n, a dose threshold value Dth of a threshold value model, a pattern area density ρ″, and a distribution function g(x) are used. The proximity effect correction dose Dp(x) can be obtained as a relative value standardized by defining the base dose D_{base} to be 1.

Next, the shot data generation unit 70 calculates, for each pixel, an incident dose D(x) (amount of dose) with which the pixel concerned is irradiated. The incident dose D(x) can be calculated, for example, by multiplying a base dose D_{base} by a proximity effect correction dose Dp and a pattern area density ρ′. The base dose D_{base} can be defined by Dth/(1/2+η), for example. Thereby, it is possible to obtain an incident dose D(x) for each pixel, for which a proximity effect has been corrected, based on a layout of a plurality of figure patterns defined by the writing data. Alternatively, it is also preferable that the shot data generation unit 70 defines an incident dose D(x) for each pixel by using an incident dose D(x) standardized regarding the base dose D_{base} as 1. In that case, for example, the incident dose D(x) can be calculated by multiplying the proximity effect correction dose Dp and the pattern area density p′.

Next, the shot data generation unit 70 generates a dose map whose element is an incident dose D(x) of each pixel 36. In other words, each pixel (position) (x, y) and its incident dose D(x) are relatedly defined. The generated dose map is stored in the storage device 142. The shot data generation unit 70 generates a dose map with respect to the whole of the writing region 30 where writing processing is performed in accordance with the writing data (chip data).

In the writing schedule generation step (S110), the writing control unit 76 generates a writing schedule which defines the order of shot of each pixel defined in the dose map. Thereby, for each shot, positions and dose amounts having been irradiated by the time (writing time) of performing the shot concerned can be known.

The influence range of the global positional deviation amount is from about several hundreds of μm to about several mm. Therefore, the influence range of the global positional deviation amount is larger than the beam array size (x direction and y direction), such as several tens of μm, of the multiple beams 20. Then, first, the writing control unit 76 virtually divides the region of the target object 101 surface into a plurality of global mesh regions 11 by a predetermined size as shown in FIG. 15. The size of the global mesh region 11 is preferably about 1/10 of the influence range of the global positional deviation amount, such as from about several tens of μm to about several hundreds of μm. For example, when the beam array size is about 80 μm, the size of the global mesh region 11 is preferably set to be about its half, namely, about 40 μm. However, the size of the global mesh region 11 is not limited to be smaller than the beam array size, and may be equal to or larger than the beam array size.

In the dose distribution generation step (S112), the dose distribution generation unit 50 calculates a dose distribution of electron beams applied to a plurality of global mesh regions 11 (xi, yi) (processing region) which are obtained by dividing the writing region 30 of the target object 101 into meshes. In other words, the dose distribution generation unit 50 generates a dose distribution of electron beams applied to a plurality of global mesh regions 11 (xi, yi) (processing region) which are obtained by dividing the writing region 30 of the target object 101 into meshes. Specifically, it operates as follows: The dose distribution generation unit 50 generates, based on the writing schedule, a dose distribution showing a dose to each global mesh region 11 at the time of beam irradiation to each global mesh region 11 (xi, yi) (a position example) of the target object 101 when a pattern is written by irradiation with the multiple beams 20. For example, the dose distribution generation unit 50 generates, for each of a plurality of shots of the multiple beams 20, a dose distribution showing doses to each global mesh region 11 having been applied by the time of completion of the shot concerned onto the coordinates (xj, yj) of the target object 101. i indicates the index of the global mesh region 11. j indicates the index of a shot number. The coordinates (xj, yj) indicate a reference position of the shot concerned, and for example, indicate the coordinates irradiated with the center beam of the multiple beams 20. The dose to each global mesh region 11 is calculated by, referring to the dose map, summing incident doses with which each global mesh region 11 (xi, yi) is irradiated.

In the distortion distribution generation step (S114), the distortion distribution generation unit 52 generates, using the dose distribution, a distortion distribution which defines the amount of distortion, at each position of the target object 101, occurring from an irreversible deformation of the target object 101. That is, the distortion distribution generation unit 52 generates, using the dose distribution, a distortion distribution which defines the amount of distortion occurring in the target object 101. Specifically, it operates as follows. The distortion distribution generation unit 52 calculates the amount of distortion occurring at each global mesh region 11 (xi, yi), at each time of beam irradiation to each global mesh region 11 (a position example) of the target object 101, so as to generate a distortion distribution. For example, the distortion distribution generation unit 52 calculates, for each shot, the amount of distortion occurring in each global mesh region 11 (xi, yi) at the time of completion of the shot concerned to the coordinates (xj, yj). At the surface of the global mesh region 11 irradiated with the multiple beams 20 or at its vicinity (henceforth, called the surface), irreversible compressive deformation occurs due to beam irradiation, and at the other part of the surface of the other global mesh region 11, tension occurs due to stress by compressive strain at the surface of the global mesh region 11 irradiated by beams. As a result, distortion occurs on the surface of each global mesh region 11 (xi, yi).

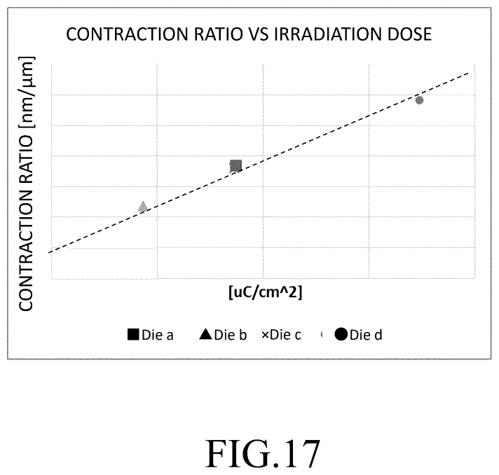

FIG. 17 is a graph showing an example of a relationship between a substrate contraction ratio and a dose according to the first embodiment. In FIG. 17, the ordinate axis represents a contraction ratio, and the abscissa axis represents a dose. In the example of FIG. 17, dies a to d are written at variable pattern area densities ρ and irradiation doses D. A distortion amount (contraction ratio: ΔL/L) at each die is calculated, and then, a relationship between a distortion amount (contraction ratio) and ρD (total dose per unit area) is calculated. L indicates a substrate size, and ΔL indicates a positional deviation amount. As shown in the example of FIG. 17, the distortion (contraction ratio) increases in proportion to ρD. Therefore, the distortion amount (contraction ratio) can be calculated using a dose defined in the dose distribution. In other words, the target object 101 deforms irreversibly depending on a dose distribution of an electron beam.

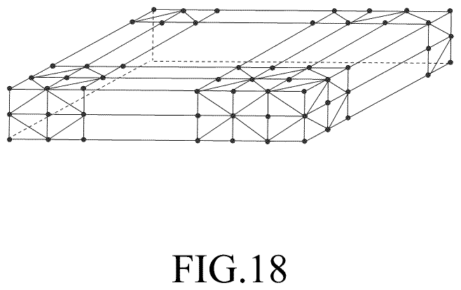

FIG. 18 is an illustration showing an example of a model by a finite element method according to the first embodiment. The example of FIG. 18 shows the state where a 6-inch mask serving as an example of the target object 101 is divided by a triangular pyramid element. One triangular pyramid element has four vertices, and each vertex has three-dimensional displacement information of a displacement vector u=(uₓ, u_{y}, u_{z}). That is, variables, totally 4×3=12 variables, exist in one unit element. In a relational expression ε=Bu between the displacement vector u(12×1) and the distortion vector ε(6×1), “distortion-displacement” matrix M1(6×12) of the unit element is expressed by the following equation (1) as an example.

$${M}_{1} = [ \begin{matrix}- 1 & 0 & 0 & 1 & 0 & 0 & 0 & 0 & 0 & 0 & 0 & 0 \\ 0 & - 1 & 0 & 0 & 0 & 0 & 0 & 1 & 0 & 0 & 0 & 0 \\ 0 & 0 & - 1 & 0 & 0 & 0 & 0 & 0 & 0 & 0 & 0 & 1 \\ - 1 & - 1 & 0 & 0 & 1 & 0 & 1 & 0 & 0 & 0 & 0 & 0 \\ 0 & - 1 & - 1 & 0 & 0 & 0 & 0 & 0 & 1 & 0 & 1 & 0 \\ - 1 & 0 & - 1 & 0 & 0 & 1 & 0 & 0 & 0 & 1 & 0 & 0\end{matrix} ] \qquad ( 1 )$$

In a relational expression σ=Dε between the stress vector σ(6×1) and the distortion vector ε(6×1), a material property matrix M₂(6×6) of a unit element is expressed by the following equation (2) using Young's modulus E and Poisson's ratio ν of a quartz substrate.

$${M}_{2} = \frac{E}{( 1 - 2 v ) ( 1 + v )} [ \begin{matrix}1 - v & v & v & 0 & 0 & 0 \\ v & 1 - μ & v & 0 & 0 & 0 \\ v & v & 1 - v & 0 & 0 & 0 \\ 0 & 0 & 0 & \frac{1 - 2 v}{2} & 0 & 0 \\ 0 & 0 & 0 & 0 & \frac{1 - 2 v}{2} & 0 \\ 0 & 0 & 0 & 0 & 0 & \frac{1 - 2 v}{2}\end{matrix} ] \qquad ( 2 )$$

Distortion e of the substrate surface generated by a charged particle beam dose Q(=ρD) is defined by the following equation (3) using coefficients c₀ and c₁.

$$e = {c}_{0} + {c}_{1} \cdot Q \qquad ( 3 )$$

Supposing that a shearing distortion generated by charged particle beam irradiation is zero, a distortion vector ε of a unit element can be defined by the following equation (4).

$${ϵ}^{t} = \{ \begin{matrix}e & e & e & 0 & 0 & 0\end{matrix} \} \qquad ( 4 )$$

A stiffness matrix per unit element is expressed by the following equation (5).

$${B}^{t} {{M}_{2}}^{t} Bu = {B}^{t} {{M}_{2}}^{t} ε \qquad ( 5 )$$

In the equation (5), t indicates a transposed matrix. Combining all the elements in the above equations, a displacement vector U of all the vertices, a whole stiffness matrix K, and an equivalent nodal force f are defined by the following equations (6-1), (6-2), and (6-3).

$$\int ( {B}^{t} {{M}_{2}}^{t} B ) dV \cdot U = \int ( {B}^{t} {{M}_{2}}^{t} ε ) dV \qquad ( 6 - 1 )$$

$$K = \int ( {B}^{t} {{M}_{2}}^{t} B ) dV \qquad ( 6 - 2 )$$

$$f = \int ( {B}^{t} {{M}_{2}}^{t} ε ) dV \qquad ( 6 - 3 )$$

Consequently, the following equation (7) is obtained.

$$KU = f \qquad ( 7 )$$

Finally, a total displacement vector U can be obtained by the following equation (8).

$$U = {K}^{- 1} f \qquad ( 8 )$$

The distortion e of each element and the distortion vector & of the equation (4) are obtained by substituting a value of an element of the dose distribution into Q of the equation (3). Thereby, a distortion amount of each global mesh region 11 at the time of beam shot to the coordinates (xi, yi) is calculated in order to generate a distortion distribution.

In the displacement distribution generation step (S116), using the distortion distribution, the displacement distribution generation unit 54 generates a displacement distribution by calculating, at each beam irradiation time, an irreversible deformation amount (Δxi, Δyi, Δzi) which occurs in each global mesh region 11 (xi, yi). For example, the displacement distribution generation unit 54 generates a displacement distribution by calculating, for each shot, the amount of an irreversible deformation occurring in each global mesh region 11 when the shot concerned to the coordinates (xj, yj) is completed. For example, by solving the equation (8) by calculating f of the equation (6-3) by using the obtained distortion vector ε of each element, a total displacement vector U including a displacement vector u of each element at the time of completion of the shot concerned applied to the coordinates (xj, yj) is calculated. Thereby, it is possible to obtain an irreversible deformation amount (Δxi, Δyi, Δzi) generated in each global mesh region 11 (xi, yi) at the time of completion of the shot concerned to the coordinates (xj, yj).

In the positional-deviation amount distribution generation step (S118), the positional-deviation amount distribution calculation unit 56 calculates a positional deviation amount distribution which defines an amount of positional deviation, at a time of irradiation by an electron beam to the target object 101, deviated from a design position due to an irreversible deformation at each position of the target object 101 which deforms irreversibly depending on a dose distribution of the electron beam and includes a substrate body, a multilayer film arranged on the substrate body and reflecting a light, and an absorber film arranged on the multilayer film and absorbing a light. In other words, the positional-deviation amount distribution calculation unit 56 generates a positional deviation amount distribution which defines an amount of positional deviation occurring due to an irreversible deformation of the target object 101 deviated from the design position at the time of beam irradiation to each global mesh region 11 (a position example) of the target object 101 when a pattern is written by irradiation with the multiple beams 20 on the target object 101. For example, the positional-deviation amount distribution calculation unit 56 calculates a positional deviation amount at a representing position, such as the center position, of each global mesh region 11 so as to generate a positional deviation amount distribution. The positional deviation amount (dxi, dyi) due to the Nth shot at the representing position of each global mesh region 11 (xi, y i) can be obtained from the dose distribution of shots, up to the (N−1)th shot, of the global mesh region concerned. A total displacement vector U including a displacement vector u of each element at the time of completion of the shot concerned applied to the coordinates (xj, yj) can be obtained by solving the equation (8) by calculating f of the equation (6-3) by using a distortion vector & of each element obtained by calculating a distortion e of each element and the distortion vector & of the equation (4) based on the dose distribution and the equation (3). Thereby, it is possible to obtain a positional deviation amount (dxi, dyi) occurring in each global mesh region 11 (xi, yi) at the time of completion of the shot concerned applied to the coordinates (xj, yj). Due to that the surface of the substrate body of the target object 101 shrinks in the compression direction, as shown in FIG. 5, the target object 101 deforms while warping in a downward convex manner.

In the determination step (S120), the writing control unit 76 (an example of a determination unit) determines whether the positional deviation amount distribution has been generated with respect to all the shots. If the positional deviation amount distribution has not yet been generated with respect to all the shots, it returns to the dose distribution generation step (S112), and repeats each step from the dose distribution generation step (S112) to the determination step (S120) while updating the shot number to the next number until the positional deviation amount distribution has been generated with respect to all the shots. The calculated positional deviation amount distribution regarding each shot is stored in the storage device 142.

In the correction layout data generation step (S106) described above, the correction layout data generation unit 62 corrects the irradiation position of an electron beam by using defect position information which shows a defect position, without considering the positional deviation amount distribution. In other words, the correction layout data generation unit 62 corrects pattern data without considering the positional deviation amount distribution. Therefore, about the time when the vicinity of the defect 40 is written, the position of the defect 40 has deviated due to irreversible deformation of the target object 101 as described above. Then, when performing correction using the positional deviation amount distribution, the correction unit 58 corrects the irradiation position of the electron beam, which has been corrected without considering the positional deviation amount distribution, while considering the positional deviation amount distribution. In other words, the correction unit 58 corrects the pattern data, which has been corrected without considering the positional deviation amount distribution, while considering the positional deviation amount distribution. It is specifically described below.

In the data correction step (S130), the correction amount calculation unit 57 calculates, using the positional deviation amount distribution, the amount of correction for the irradiation position of an electron beam so that a defect occurred in the target object 101 may be included in the region where the absorber film 19 remains after writing. The correction unit 58 corrects, using the positional deviation amount distribution, pattern data so that the defect 40 occurred in the target object 101 may be included in the region where the absorber film 19 remains after writing. In other words, the correction unit 58 corrects pattern data by using a correction amount. Specifically, it operates as follows. For example, the correction unit 58 corrects pattern data by adding a positional deviation amount (correction amount) at the time of applying the multiple beams 20 to the original portion where the defect 40 exists to the coordinates of the pattern data which has been corrected without considering the positional deviation amount distribution. Thereby, in the actual writing processing, it is possible to write the pattern of the absorber film 19 on the defect 40 which has moved due to positional deviation of the target object 101.

After the preprocessing described above is completed, actual writing processing is performed.

In the writing step (S140), the irradiation position is corrected using the correction amount, and a pattern is written on the target object 101 with the multiple beams 20 (electron beam). Specifically, it operates as follows. First, the shot data generation unit 70 generates anew the dose map in which the dose is defined for each pixel. In the present case, since the pattern layout data has been corrected, a dose map is generated anew. The contents of the method for generating the dose map are the same as those described above. Next, the shot data generation unit 70 calculates an irradiation time for each pixel 36 by using an incident dose D(x) (amount of dose) defined in the dose map. The irradiation time for each pixel 36 can be calculated by dividing the incident dose D(x) of the pixel concerned by a current density J. In the case where the incident dose D(x) defined in the dose map is standardized regarding the base dose Dbase as 1, the irradiation time for each pixel 36 can be calculated by dividing, by the current density J, the value obtained by multiplying the incident dose D(x) by the base dose Dbase.

The data processing unit 72 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 76, the writing mechanism 150 writes a pattern on the target object 101 with the multiple beams 20 (electron beam) whose irradiation position has been corrected using the correction amount.

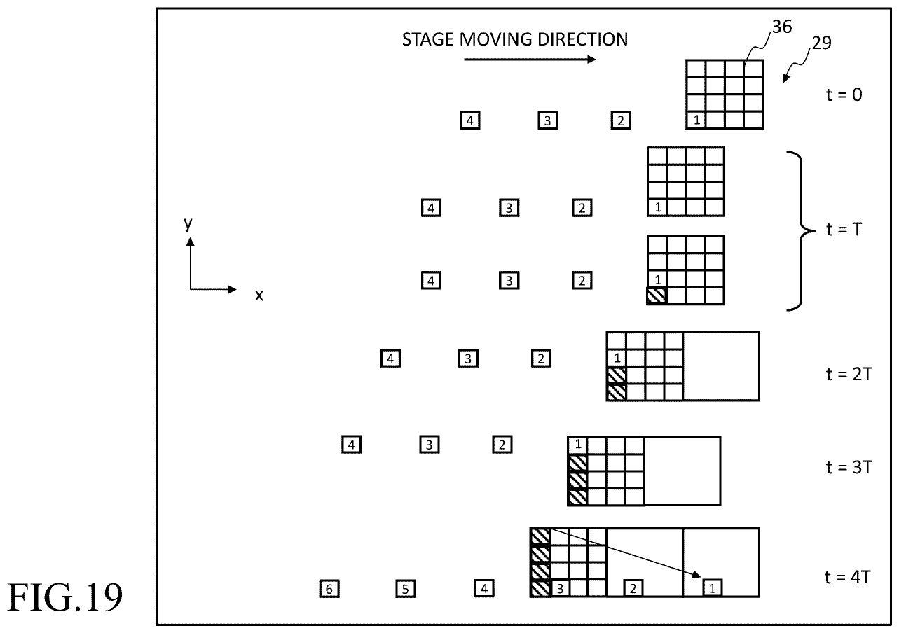

FIG. 19 is an illustration for explaining an example of a multiple beam writing operation according to the first embodiment. FIG. 19 shows the case where the inside of each sub-irradiation region 29, which includes the beam irradiation position of one beam of the multiple beams 20 and is surrounded by the beam pitch (pitch between beams), is written with four different beams. The example of FIG. 19 shows a writing operation where the XY stage 105 continuously moves at the speed at which it moves the distance of two beam pitches during writing a ¼ region, namely the region of 1/(the number of beams used for irradiation), in each sub-irradiation region 29. FIG. 19 shows the case where each sub-irradiation region 29 is composed of 4×4 pixels, for example.

In the writing operation shown in FIG. 19, for example, while the XY stage 105 moves the distance of two beam pitches in the x direction, four different pixels 36 in the same sub-irradiation region 29 are written (exposed) by applying four shots of the multiple beams 20 at a shot cycle T with sequentially shifting the irradiation position (pixel 36) by the deflector 209. In order that the relative position between the irradiation region 34 and the substrate 101 may not deviate by the movement of the XY stage 105 while the four pixels 36 are written (exposed), the irradiation region 34 is made to follow the movement of the XY stage 105 by collective deflection of all of the multiple beams 20 by the deflector 208. In other words, a tracking control is performed. In the example of FIG. 19, although the time period during which the XY stage 105 moves the distance of two beam pitches in the x direction is described as an example of a tracking cycle, it is not limited thereto. A time period during which the XY stage 105 moves the distance larger than the distance of two beam pitches, such as the distance of eight beam pitches or the distance of sixteen beam pitches may also be used.

After one tracking cycle is completed, tracking is reset to return to the previous (last) tracking start position. Since writing of the pixels in the first column from the left of each sub-irradiation region 29 has been completed, in the next tracking cycle after resetting the tracking, first, the deflector 209 provides deflection such that the writing position of a beam which is different from that used for the first pixel column is adjusted (shifted) to write the second pixel column from the left still not having been written in each sub-irradiation region 29, for example. By repeating this operation during writing the stripe region 32, as shown in the middle part of FIG. 15, the position of the irradiation region 34 (34a to 340) of the multiple beams 20 is sequentially moved (shifted) to perform writing.

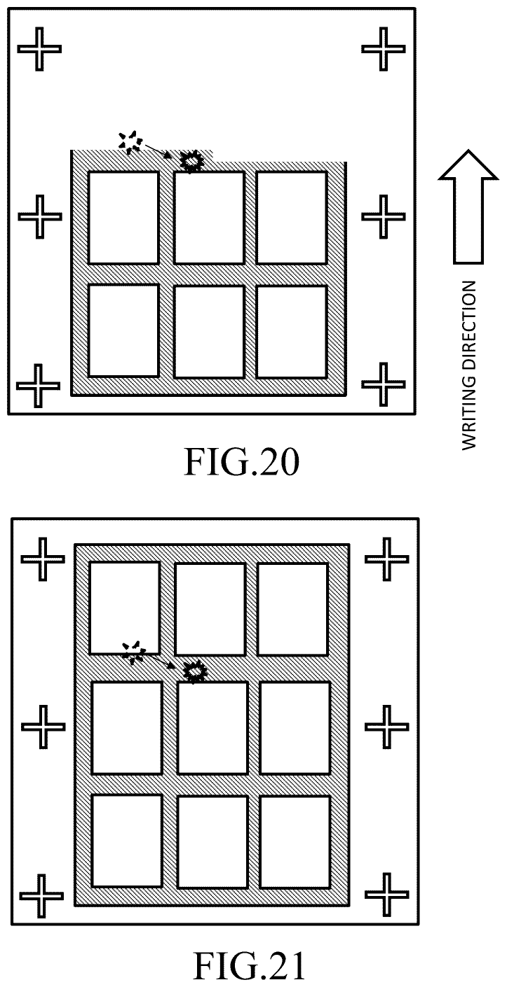

FIG. 20 is a top view showing an example of a positional relationship between a defect and an absorber film at the time of writing a defect portion according to the first embodiment.

FIG. 21 is a top view showing an example of a positional relationship between a defect and an absorber film after completing writing according to the first embodiment.

In the first embodiment, the pattern layout is corrected in consideration of the position of the defect 40 moving associated with irreversible deformation of the target object 101. As a result, as shown in FIG. 20, at the time of writing the defect portion, the pattern for the absorber film 19 to remain is written on the defect 40. Then, in accordance with the advance of writing processing, deformation of the target object 101 increases (progresses). Along with this, the positions of the defect 40 and each pattern also move. However, since the defect 40 has the same locus as that of the pattern for the absorber film 19 to remain, which has already been written on the defect 40, it is possible to include, even after writing, the defect 40 in the region of the pattern for the absorber film 19 to remain as shown in FIG. 21. Therefore, in that state, by performing development processing and etching processing for the target object 101, the state where defect 40 is included in the region of the pattern of the absorber film 19 can be maintained.

As described above, according to the first embodiment, correction can be performed for a defect not to deviate out of the absorber pattern region of the EUV mask substrate which has been irreversibly deformed by irradiation with a charged particle beam.

Embodiments have been explained referring to specific examples described above. However, the present invention is not limited to these specific examples. Furthermore, processing described in each embodiment may be executed by a computer. A program for causing a computer to implement such processing may be stored in a non-transitory tangible computer-readable storage medium such as a magnetic disk drive.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Although, in the examples described above, the positional deviation amount distribution is generated until all the shots have been completed, it is not limited thereto. It is sufficient to have a positional deviation amount distribution at the time of writing a defect position. Therefore, generating positional deviation amount distributions until the time of writing a defect position is also acceptable. Furthermore, in the case where a plurality of defects exist, it is also acceptable to add, for each defect portion, a positional deviation amount at the time of writing the defect portion concerned to the defect portion concerned and its peripheral pattern data. Furthermore, although pattern data is corrected in order to move the pattern position, correction may be performed using a beam deflection amount, a beam array rotation, or a magnification.

Furthermore, any electron beam writing method, electron beam writing apparatus, and program (or non-transitory computer-readable storage medium storing a program) that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A charged particle beam writing method comprising:
calculating a positional deviation amount distribution which defines an amount of positional deviation, at a time of irradiation by a charged particle beam to a target object, deviated from a design position due to an irreversible deformation at each position of the target object which deforms irreversibly depending on a dose distribution of the charged particle beam and includes a substrate body, a multilayer film arranged on the substrate body and reflecting a light, and an absorber film arranged on the multilayer film and absorbing the light;
calculating, using the positional deviation amount distribution, a correction amount for correcting an irradiation position of the charged particle beam such that a defect occurred in the target object is included in a region where the absorber film remains after writing; and
correcting the irradiation position by using the correction amount, and writing a pattern on the target object with the charged particle beam.

2. The method according to claim 1, further comprising:
correcting the irradiation position of the charged particle beam by using defect position information which shows a defect position, without considering the positional deviation amount distribution, wherein
in a case where correcting is performed using the positional deviation amount distribution, the irradiation position of the charged particle beam, which has been corrected without considering the positional deviation amount distribution, is corrected considering the positional deviation amount distribution.

3. The method according to claim 1, further comprising:
calculating a dose distribution of charged particle beams each applied to any one of a plurality of processing regions obtained by dividing a writing region of the target object into meshes; and
generating, using the dose distribution, a distortion distribution which defines an amount of distortion at each position of the target object occurring from the irreversible deformation of the target object.

4. A charged particle beam writing apparatus comprising:
a positional-deviation amount distribution calculation circuit configured to calculate a positional deviation amount distribution defining an amount of positional deviation, at a time of irradiation by a charged particle beam to a target object, deviated from a design position due to an irreversible deformation at each position of the target object which deforms irreversibly depending on a dose distribution of the charged particle beam and includes a substrate body, a multilayer film arranged on the substrate body and reflecting an EUV light, and an absorber film arranged on the multilayer film and absorbing the EUV light;
a correction amount calculation circuit configured to calculate, using the positional deviation amount distribution, a correction amount for correcting an irradiation position of the charged particle beam such that a defect occurred in the target object is included in a region where the absorber film remains after writing; and
a writing mechanism configured to write a pattern on the target object with the charged particle beam whose irradiation position has been corrected using the correction amount.

5. A non-transitory computer-readable storage medium storing a program for causing a computer to execute processing comprising:
calculating a positional deviation amount distribution which defines an amount of positional deviation, at a time of irradiation by a charged particle beam to a target object, deviated from a design position due to an irreversible deformation at each position of the target object which deforms irreversibly depending on a dose distribution of the charged particle beam and includes a substrate body, a multilayer film arranged on the substrate body and reflecting an EUV light, and an absorber film arranged on the multilayer film and absorbing the EUV light;
storing the positional deviation amount distribution having been calculated, in a storage device; and
reading the positional deviation amount distribution from the storage device, calculating, by using the positional deviation amount distribution, a correction amount for correcting an irradiation position of the charged particle beam such that a defect occurred in the target object is included in a region where the absorber film remains after writing, and outputting the correction amount.
